(19) United States
(12) Patent Application Publication
(10) Pub. No.: US 2015/0086789 A1
(43) Pub. Date: Mar. 26, 2015

(54) TRANSPARENT CONDUCTIVE FILM

(71) Applicant: NITTO DENKO CORPORATION, Ibaraki-shi, Osaka (JP)

(72) Inventors: Daisuke Kajihara, Ibaraki-shi (JP); Tomotake Nashiki, Ibaraki-shi (JP); Motoki Haishi, Ibaraki-shi (JP)

(73) Assignee: NITTO DENKO CORPORATION, Ibaraki-shi, Osaka (JP)

(21) Appl. No.: 14/377,122

(22) PCT Filed: May 31, 2013
(86) PCT No.: PCT/JP2013/065231

§ 371 Date: Aug. 6, 2014

(30) Foreign Application Priority Data
Jun. 7, 2012 (JP) 2012-129916

(51) Int. Cl. H05K 1/02; H05K 1/09; G06F 3/041

(52) U.S. Cl. CPC H05K 1/0213; G06F 3/041; H05K 1/0274; H05K 1/09; H05K 2201/0776
USPC 428/412; 428/480; 428/523

(57) ABSTRACT

A transparent conductive film includes a film base and a polycrystalline layer of indium tin oxide formed on the film base. The polycrystalline layer has a thickness of 10 nm to 30 nm, an average value of gain size of 180 nm to 270 nm, and a carrier density of greater than 6×10²⁰/cm³ and less than or equal to 9×10²⁰/cm³.

### TECHNICAL FIELD

The present disclosure relates to a transparent conductive film applicable to an input display unit capable of inputting information by a touch of a finger, a stylus pen, or the like.

### BACKGROUND ART

In the related art, a transparent conductive film including a film base and a polycrystalline layer of indium tin oxide formed thereon is known (Patent Document 1). Such a transparent conductive film has low specific electrical resistance (also referred to as volume resistivity) and shows good electrical conductivity.

### DOCUMENT LIST

### Patent Document(s)

Patent Document 1: Japanese Laid-Open Patent Publication No. H09-286070

### SUMMARY OF INVENTION

### Technical Problem

However, recently, widely used smart phones or slate PCs require a transparent conductive film having improved properties. Particularly, in such applications, the transparent conductive film of the related art still has a drawback that a specific electrical resistance is high.

It is an object of the present disclosure to provide a transparent conductive film that has high transmittance and low specific electrical resistance.

### Solution to Problem

In order to solve the aforementioned problem, a transparent conductive film of the present disclosure includes a film base and a polycrystalline layer of indium tin oxide formed on the film base, the polycrystalline layer having a thickness of 10 nm to 30 nm, an average value of gain size of 180 nm to 270 nm, and a carrier density of greater than 6×10²⁰/cm³ and less than or equal to 9×10²⁰/cm³.

Further, the polycrystalline layer has a Hall mobility of 21 cm²/V·sec to 30 cm²/V·sec.

Further, an amount of tin atoms in the polycrystalline layer of indium tin oxide is greater than 6% by weight and 15% by weight with respect to a weight of a sum of indium atoms and the tin atoms.

Further, the film base is made of one of polyethylene terephthalate, polycycloolefin and polycarbonate.

### Advantageous Effects of Invention

According to the present disclosure, the polycrystalline layer has a thickness of 10 nm to 30 nm, an average value of gain size of 180 nm to 270 nm, and a carrier density of greater than 6×10²⁰/cm³ and less than or equal to 9×10²⁰/cm³. That is, since a decrease in gain size that may occur due to an existence of impurities is suppressed, a decrease in Hall mobility can be sufficiently suppressed, and, in addition, a good transmittance can be achieved. Therefore, a transparent conductive film having high transmittance and low specific electrical resistance can be provided.

### BRIEF DESCRIPTION OF DRAWINGS

FIG. 1 is a cross sectional diagram showing a configuration of a transparent conductive film of an embodiment of the present disclosure.

FIG. 2 is an electron microscope image showing grain boundaries in a polycrystalline layer.

### DESCRIPTION OF THE PREFERRED EMBODIMENTS

Further features of the present disclosure will become apparent from the following detailed description of exemplary embodiments with reference to the accompanying drawings.

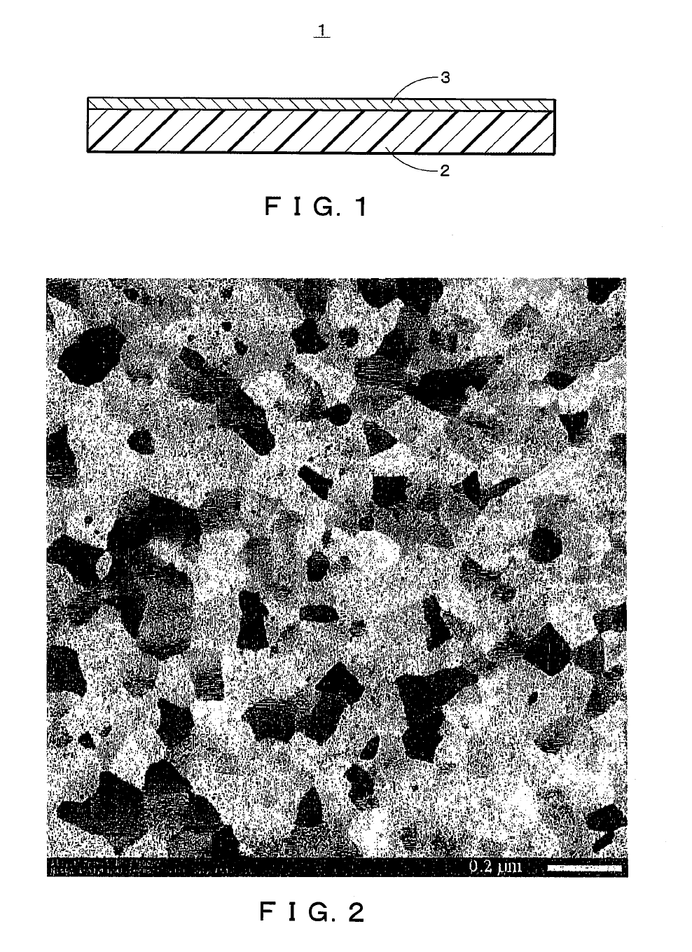

As shown in FIG. 1, a transparent conductive film 1 of the present embodiment includes a film base 2 and a polycrystalline layer 3 of indium tin oxide formed on the film base. The polycrystalline layer 3 has a thickness of 10 nm to 30 nm, an average value of gain size of 180 nm to 270 nm, and a carrier density of greater than 6×10²⁰/cm³ and less than or equal to 9×10²⁰/cm³.

Since such a transparent conductive film has a large gain size, an amount of electrons that can move in the polycrystalline layer increases, and the specific electrical resistance significantly decreases. Further, since the thickness of the polycrystalline layer is small, transmittance is high.

The film base 2 having good transparency as well as good heat-resistance property is preferably used. In order to produce a transparent conductive film having a good quality, the film base has a thickness of preferably 10 μm to 50 μm.

A material forming the film base is preferably one of polyethylene terephthalate, polycycloolefin and polycarbonate. The film base may have, on its surface, an easy adhesion layer (anchor coating layer) for increasing an adhesiveness between the polycrystalline layer of indium tin oxide and the film base, a refraction index adjustment layer (index-matching layer) for adjusting a reflective index of the film base, and a hard coat layer (hard coating layer) for increasing an abrasion-resistant property of the film base.

The polycrystalline layer 3 can be typically obtained by forming an amorphous layer of indium tin oxide on the surface of film base by sputtering and by applying a heat-treatment to the amorphous layer.

The aforementioned sputtering is a method in which a cation in a plasma generated in a low pressure gas is collided on a target material, which is a negative electrode, and a substance ejected from a surface of the aforementioned target material is deposited on a substrate.

An average value of gain size for the polycrystalline layer 3 is 180 nm to 270 nm, and preferably, 190 nm to 250 nm. Since the aforementioned polycrystalline layer has crystal grains (grains) of such a size, electrons in the polycrystalline layer can move easily, and specific electrical resistance decreases. In this case, the Hall mobility of the polycrystalline layer is 21 cm²/V·sec to 30 cm²/V·sec, and preferably, 24 cm²/V·sec to 28 cm²/V·sec.

The crystal grain of the aforementioned size can be obtained by forming the amorphous layer in such a manner that impurities taken into the amorphous layer of the indium tin oxide decreases as much as possible and thereafter applying a heat-treatment to the amorphous layer. A method of reducing an amount of impurities taken in by the amorphous layer specifically includes, for example, a method of removing volatile components (moisture and organic gas) in the film base by reducing a pressure of a degree of vacuum of a sputtering apparatus that forms an amorphous layer of indium tin oxide to less than or equal to 5×10⁻⁵ Pa.

A carrier density of the polycrystalline layer is greater than 6×10²⁰/cm³ and less than or equal to 9×10²⁰/cm³, and preferably, 6.5×10²⁰/cm³ to 8×10²⁰/cm³. Since such a polycrystalline layer has an increased number of electrons that can move in the polycrystalline layer, the specific electrical resistance decreases.

The polycrystalline layer showing such a carrier density can be obtained by adjusting an amount of tin atoms in the amorphous layer of the indium tin oxide to be greater than 6% by weight and less than or equal to 15% by weight with respect to a weight of a sum of indium atoms and the tin atoms, and preferably 7% by weight to 12% by weight, and applying a heat treatment on the amorphous layer such that the crystal grains grow large.

A specific electrical resistance of the polycrystalline layer satisfying the conditions of the aforementioned gain size and the carrier density is less than 4.0×10⁻⁴ Ω·cm, and preferably 3.0×10⁻⁴ Ω·cm to 3.8 ×10⁻⁴ Ω·cm.

According to the present embodiment, the polycrystalline layer has a thickness of 10 nm to 30 nm, an average value of the gain size of the polycrystalline layer of 180 nm to 270 nm, and a carrier density of greater than 6×10²⁰/cm³ and less than or equal to 9×10²⁰/cm³. That is, since a decrease in gain size that may occur due to an existence of impurities is suppressed, a decrease in Hall mobility can be sufficiently suppressed, and, in addition, good transmittance can be achieved. Therefore, a transparent conductive film having high transmittance and low specific electrical resistance can be provided.

### EXAMPLES

Examples of the present disclosure will be described.

Firstly, a film base of a polyethylene terephthalate film having a thickness of 23 μm was placed in a sputtering apparatus, and the pressure was reduced such that a degree of vacuum in the sputtering apparatus becomes 5×10⁻⁵ Pa. Moisture and an organic gas in the sputtering apparatus and in the film base were removed. Then, a mixed gas of 98% by volume of argon gas and 2% by volume of oxygen gas was introduced into the aforementioned sputtering apparatus and an amorphous layer of indium tin oxide having a thickness of 25 nm was formed on one side of the film base such that an amount of tin atoms in the amorphous layer is 10% by weight with respect to a weight of a sum of indium atoms and the tin atoms.

Then, the film base on which the amorphous layer of indium tin oxide is formed was removed from a sputtering apparatus and crystallized by applying a heat treatment on the amorphous layer in a heating oven at 140° C. for 90 minutes, and a polycrystalline layer with an average value of gain size of 207 nm was obtained.

Then, the transparent conductive film of Examples 1 described above was measured and evaluated by a following method.

### (1) Average Value of Grain Size

Using a transmission electron microscope (manufactured by Hitachi, Ltd., product name “H-7650”), a surface of the polycrystalline layer was observed with a direct magnification of 100,000 times and photographed at an acceleration voltage of 10 kV. An image analysis process was carried out on the photograph and grain boundaries were identified. An image after the image analysis process is shown in FIG. 2. Then, based on a result of the identification, the largest diameter of a shape of each crystal grain was taken as a grain size (nm), and an average value thereof was determined.

### (2) Carrier Density and Hall Mobility

A carrier density and a hall density of the polycrystalline layer were measured using a Hall effect measurement system (manufactured by BIO-RAD Laboratories, Inc., product name “HL5500PC”).

### (3) Specific Electrical Resistance

A specific electrical resistance of the polycrystalline layer was determined by multiplying a surface resistance value obtained by a 4-probe method by the thickness of the polycrystalline layer.

(4) Crystallinity after Heat Treatment

Presence or absence of crystal grains was observed by using a transmission electron microscope (manufactured by Hitachi, Ltd., product name “H-7650”).

Results of measurement and evaluation of for (1) to (4) described above are indicated in Table 1. Characteristics of a transparent conductive film of Example 4 disclosed in Japanese Laid-Open Patent Publication No. H09-286070 are indicated as Reference Example in Table 1.

TABLE 1

| | | REFERENCE |
|---|---|---|
| | EXAMPLE | EXAMPLE |
| AMOUNT OF TIN ATOM | 10 | 10 |
| (WEIGHT %) | | |
| CARRIER DENSITY | 7.3 | 0.56 |
| (×10²⁰/cm³) | | |
| HALL MOBILITY (cm²/ | 26 | 31 |
| V · sec) | | |
| SPECIFIC RESISTANCE | 3.3 | 36 |
| (×10⁻⁴ Ω · cm) | | |
| CRYSTALLINITY AFTER | POLYCRYSTALLINE | AMORPHOUS |
| HEAT TREATMENT | | |

Referring to Table 1, it can be seen that, with the transparent conductive film of the Example, since crystal grains having a large grain size is formed, a value of Hall mobility is equivalent to that of Reference Example for an amorphous material and a value of the carrier density has largely increased, and as a result, a specific electrical resistance has decreased. Therefore, according to this Example, it was found that a transparent conductive film having a high transmittance and a low specific electrical resistance can be produced.

### INDUSTRIAL APPLICABILITY

The transparent conductive film of the present disclosure is preferably used in smartphones or tablet terminals (also referred to as Slate PCs), but it is not particularly limited thereto.

### LIST OF REFERENCE SIGNS

1 transparent conductive film
2 film base
3 polycrystalline layer

1. A transparent conductive film comprising a film base and a polycrystalline layer of indium tin oxide formed on the film base,
the polycrystalline layer having a thickness of 10 nm to 30 nm, an average value of gain size of 180 nm to 270 nm, and a carrier density of greater than 6×10²⁰/cm³ and less than or equal to 9×10²⁰/cm³.

2. The transparent conductive film according to claim 1, wherein the polycrystalline layer has a Hall mobility of 21 cm²/V·sec to 30 cm²/V·sec.

3. The transparent conductive film according to claim 1, wherein an amount of tin atoms in the polycrystalline layer of indium tin oxide is greater than 6% by weight and less than or equal to 15% by weight with respect to a weight of a sum of indium atoms and the tin atoms.

4. The transparent conductive film according to claim 1, wherein the film base is made of one of polyethylene terephthalate, polycycloolefin and polycarbonate.
